(19) United States
(12) Patent Application Publication
(10) Pub. No.: US 2025/0146133 A1
(43) Pub. Date: May 8, 2025

(54) SUBSTRATE SUPPORTING UNIT, APPARATUS FOR TREATING SUBSTRATE, AND METHOD OF MANUFACTURING SEMICONDUCTOR DEVICE

(71) Applicant: Samsung Electronics Co., Ltd., Suwon-si (KR)

(72) Inventors: Yeontae Kim, Suwon-si (KR); Yihwan Kim, Suwon-si (KR); Minsu Lee, Suwon-si (KR); Hyeonjin Jeon, Suwon-si (KR); Hyeongun Jeon, Suwon-si (KR)

(21) Appl. No.: 18/672,023

(22) Filed: May 23, 2024

(30) Foreign Application Priority Data
Nov. 7, 2023 (KR) 10-2023-0152884

(51) Int. Cl. C23C 16/458; C23C 16/455; C23C 16/46; H01L 21/687

(52) U.S. Cl. CPC C23C 16/4584; C23C 16/45544; C23C 16/4586; C23C 16/463; H01L 21/68785

(57) ABSTRACT

A substrate support unit includes a chuck having an upper surface on which to mount a substrate, and including a heater for heating the substrate; a shaft assembly supporting a lower portion of the chuck, and including an electric line connected to the heater; a support assembly having an accommodation space surrounding and accommodating a portion of the shaft assembly, and supporting the shaft assembly; a seal sealing a lower portion of the accommodation space; an inlet communicating with the accommodation space and configured to transfer cooling gas for cooling the electric line into the accommodation space, the inlet being disposed in one of the support assembly and the seal; and an outlet disposed in the support assembly, communicating with the accommodation space, and configured to transfer the cooling gas out of the support assembly.

### CROSS-REFERENCE TO RELATED APPLICATION(S)

This application claims benefit of priority to Korean Patent Application No. 10-2023-0152884 filed on Nov. 7, 2023 in the Korean Intellectual Property Office, the disclosure of which is incorporated herein by reference in its entirety.

### BACKGROUND

The present inventive concept relates to a substrate support unit and an apparatus for treating a substrate.

In order to manufacture a semiconductor device, such as a semiconductor memory chip, or semiconductor logic chip, or a semiconductor package including one or more semiconductor chips, multiple processes such as a deposition process, a lithography process, an etching process, a cleaning process, and the like, are required and multiple devices are used.

For example, representative methods for forming a thin film on a substrate in a deposition process include chemical vapor deposition (CVD) and atomic layer deposition (ALD). In such a deposition process, various reactants may be used to form a thin film on a surface of the substrate heated to a process temperature. In order to heat the substrate during the deposition process, a substrate support apparatus supporting the substrate is provided with a heating means for heating the substrate by receiving power through an electric line connected to a power supply source. While heating the substrate, heat generated by the heating means may be transferred to the electric line and surrounding members of the electric line, increasing resistance, which may cause defect problems such as arcing in vulnerable portions.

### SUMMARY

An aspect of the present inventive concept is to provide a substrate support unit and an apparatus for treating a substrate that can improve cooling efficiency of an internal electric line connected to a chuck and surrounding members of the electric line.

According to an aspect of the present inventive concept, a substrate support unit includes a chuck having an upper surface on which to mount a substrate, and including a heater for heating the substrate; a shaft assembly supporting a lower portion of the chuck, and including an electric line connected to the heater; a support assembly having an accommodation space surrounding and accommodating a portion of the shaft assembly, and supporting the shaft assembly; a seal sealing a lower portion of the accommodation space; an inlet communicating with the accommodation space and configured to transfer cooling gas for cooling the electric line into the accommodation space, the inlet being disposed in one of the support assembly and the seal; and an outlet disposed in the support assembly, communicating with the accommodation space, and configured to transfer the cooling gas out of the support assembly.

According to an aspect of the present inventive concept, an apparatus for treating a substrate includes a chamber; a substrate support unit disposed in the chamber and configured to support a substrate; and a gas injection unit disposed above the substrate support unit, and configured to inject process gas onto the substrate. The substrate support unit includes: a chuck having an upper surface on which to mount a substrate, and including a heater for heating the substrate; a shaft supporting a lower portion of the chuck, and including an electric line connected to the heater; a support having an accommodation space surrounding and accommodating a portion of the shaft, and supporting the shaft; a seal sealing a lower portion of the accommodation space; an inlet communicating with the accommodation space and configured to transfer cooling gas for cooling the electric line into the accommodation space, the inlet being disposed in one of the support and the seal; and an outlet disposed in the support, communicating with the accommodation space, and configured to transfer the cooling gas out of the support.

According to an aspect of the present inventive concept: an apparatus for treating a substrate includes a chamber; a substrate support unit disposed in the chamber and configured to support a substrate; and a gas injection unit disposed above the substrate support unit and configured to inject process gas onto the substrate. The substrate support unit includes: a chuck having an upper surface on which to mount a substrate, and including a heating member for heating the substrate; a shaft portion supporting a lower portion of the chuck, having an electric line connected to the heating member disposed thereon, and including a slip ring connecting the electric line to a power supply source; a support portion having an accommodation space surrounding and accommodating a portion of the shaft portion, and connected to the shaft portion to rotate the chuck; a seal sealing a lower portion of the accommodation space; an inlet communicating with the accommodation space and located to transfer cooling gas for cooling the electric line into the accommodation space, the inlet disposed in the seal; and an outlet communicating with the accommodation space and located to transfer the cooling gas from the accommodation space to an outside of the substrate support unit, the outlet connected to an opening in a rotation cylinder of the substrate support unit

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a schematic diagram of an apparatus for treating a substrate according to an example embodiment;

FIG. 2 is a schematic perspective view of a substrate support unit of an apparatus for treating a substrate according to an example embodiment;

FIG. 3 is a schematic cross-sectional view of a substrate support unit according to an example embodiment;

FIG. 4 is a schematic cross-sectional view illustrating a partial configuration of a substrate support unit according to an example embodiment;

FIG. 5 is a diagram illustrating a flow of cooling gas flowing inside a substrate support unit according to an example embodiment;

FIG. 6 is a schematic cross-sectional view of a substrate support unit according to an example embodiment; and

FIG. 7 depicts a method of manufacturing a semiconductor device, according to an example embodiment.

### DETAILED DESCRIPTION

Hereinafter, example embodiments of the present inventive concept will be described with reference to the accompanying drawings.

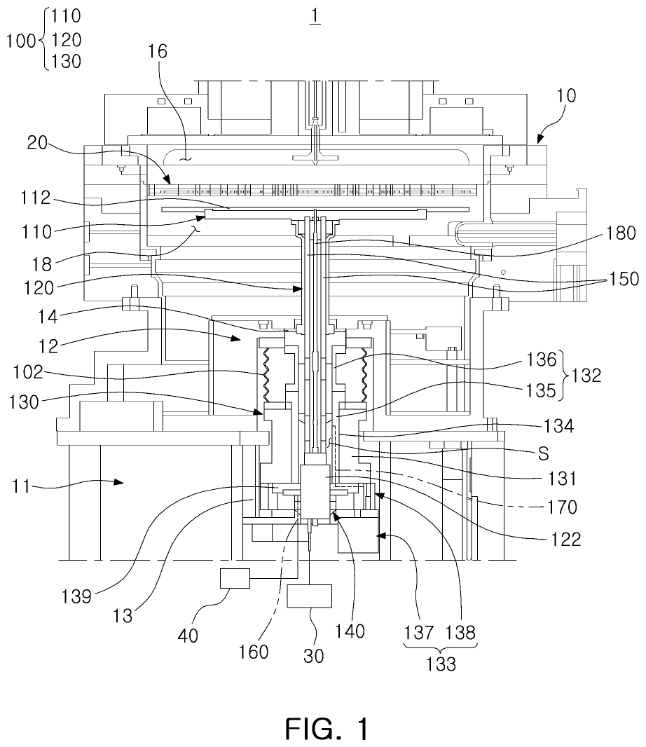

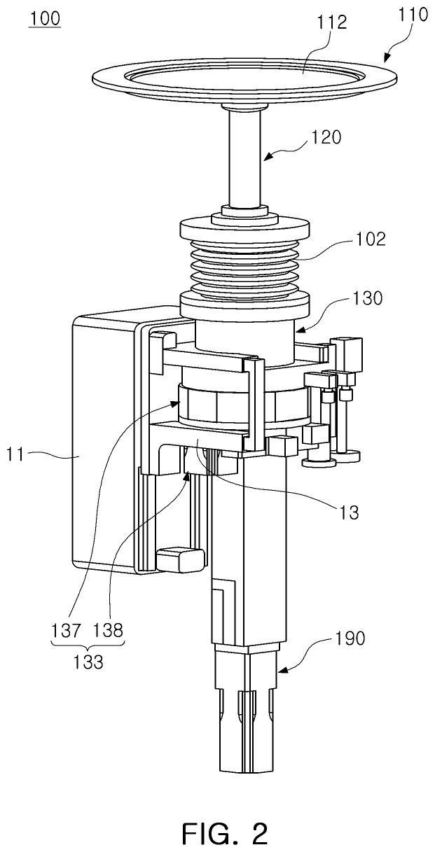

FIG. 1 is a schematic diagram of an apparatus for treating a substrate according to an example embodiment, and FIG. 2 is a schematic perspective view of a substrate support unit of an apparatus for treating a substrate according to an example embodiment.

Referring to FIGS. 1 and 2, an apparatus for treating a substrate 1 according to an example embodiment may include a chamber 10, a substrate support unit 100 disposed in the chamber 10 and supporting a substrate (not shown), and a gas injection unit 20 disposed above the substrate support unit 100 and injecting process gas onto the substrate.

The apparatus for treating a substrate 1 may be an apparatus performing any one of deposition, etching, and annealing processes. In an example embodiment, the apparatus for treating a substrate 1 may be an apparatus for forming a thin film on a substrate, for example, a chemical vapor deposition (CVD) device or an atomic layer deposition (ALD) device.

A substrate to be treated by the apparatus for treating a substrate 1 may be provided on the substrate support unit 100. The substrate may be, for example, a silicon wafer used in the manufacturing of a semiconductor integrated circuit (IC).

The chamber 10 has an internal space in which a substrate is accommodated so that one of deposition, etching, and annealing processes may be performed. In an example embodiment, the chamber 10 may have an internal space in which a deposition process occurs. The chamber 10 may be composed of an upper wall, a side wall, and a lower wall, and a passage through which a substrate may be loaded and unloaded may be provided on the side wall of the chamber 10. A gas injection unit 20 may be disposed in the internal space of the chamber 10. A plurality of supply passages (not shown) may be provided on the side wall of the chamber 10 to allow a plurality of process gases to flow into the internal space of the chamber 10. An exhaust unit (not shown) may be connected to the chamber 10 to discharge reaction by-products and residual gas in the chamber 10 externally. In an example embodiment, the exhaust unit may include a vacuum pump, and reaction by-products and residual gas in the chamber 10 may be discharged externally by a vacuum suction force generated by the vacuum pump. A cylindrical portion 12, also described as a cylinder portion, may be provided at the bottom of the chamber 10 so that a shaft portion 120 (e.g., a shaft, also described as a shaft assembly) supporting a chuck 110 of the substrate support unit 100, to be described later, penetrates the cylindrical portion 12. The cylindrical portion 12 may correspond to an internal portion of the chamber 10 having a cylindrical shape (e.g., a space formed by sidewalls of the chamber that form a cylinder shape). A bellows pipe 102 is disposed to surround the shaft portion 120 of the substrate support unit 100 to be described later, and a portion of the support unit 130 supporting the shaft portion 120 may be installed inside the cylindrical portion 12.

The gas injection unit 20 may be disposed above the substrate support unit 100 in the chamber 10 to face the substrate support unit 100. The gas injection unit 20 may be connected to a gas supply unit (not shown), and may be configured to distribute a process gas supplied from the gas supply unit and provide the process gas to an upper surface of the substrate. The gas injection unit 20 may be, for example, a shower head, and divides the internal space of the chamber 10 into a plasma region 16 and a process region 18. Plasma generated from the plasma region 16 passes through the gas injection unit 20 and is supplied to the process region 18. To this end, the gas injection unit 20 may be provided with a plurality of injecting holes (not shown).

The substrate support unit 100 may be disposed in a lower region in the chamber 10. The substrate support unit 100 may include a chuck 110 having an upper surface on which a substrate is mounted and including a heating member 112 therein, a shaft portion 120 supporting a lower portion of the chuck 110, a support portion 130 (e.g., support unit, also described as a support, support assembly, support block, or support cylinder) having an accommodation space S surrounding a portion of the shaft portion 120 and accommodating the shaft portion 120 and supporting the shaft portion 120, and a sealing member 140 for sealing a lower portion of the accommodation space S of the support portion 130. The heating member 112 of the chuck 110 may include a heat conductor such as a heating wire, heating plate, or heat induction element, and may generally be referred to as a heater. An electric line 150 connected to the heating member 112 of the chuck 110 may be disposed in or on the shaft portion 120, and the electric line 150 may be connected to a power supply source 30. A temperature sensor 180 for measuring a temperature of the chuck 110 may be disposed on the shaft portion 120. Power provided from the power supply source 30 may be supplied to the heating member 112 of the chuck 110 through the electric line 150 to heat the substrate mounted on the chuck 110. In the process of heating the substrate, resistance may increase as heat generated by the heating member 112 is transferred to the electric line 150 and surrounding members of the electric line 150. Accordingly, as the resistance of the surrounding members of the electric line 150 continues to increase due to overheating, defect phenomena such as arcing may occur in vulnerable portions.

In order to cool the electric line 150 and the surrounding members, the substrate support unit 100 according to an example embodiment of the present inventive concept may include an inlet portion 160 through which cooling gas flows into the accommodation space S of the support portion 130 sealed by the sealing member 140 and an outlet portion 170 through which the cooling gas flows out from the accommodation space S externally. Inlet portion 160 may be a first opening in the chamber 10 that allows cooling gas to flow into the accommodation space S, and may be described as an inlet or inlet port. The outlet portion 170 may be a second opening in the chamber 10 that allows exhaust gas to flow out of the chamber 10, and may be described as an outlet or an outlet port.

The substrate support unit 100 according to an example embodiment of the present inventive concept may further include a cooling gas supply unit 40 connected to the inlet portion 160. As the cooling gas supplied from the cooling gas supply unit 40 flows into the accommodation space S of the support portion 130 sealed by the sealing member 140 through the inlet portion 160, the electric line 150 and the surrounding members of the electric line 150 may be cooled, and then the cooling gas may be discharged externally through the outlet portion 170. Accordingly, by cooling the electric line 150 and surrounding members, it is possible to effectively prevent defect phenomena such as arcing in the surrounding members of the electric line 150. The cooling gas supply unit 40 may supply cooling gas consisting of air or inert gas to the inlet portion 160 (e.g., wherein air includes gases present in the surrounding environment and may include atmospheric gases). The cooling gas supply unit 40 may be connected to the inlet portion 160 and may supply cooling gas having an internal pressure of the accommodation space S of the support portion 130 higher than an external pressure. In an example embodiment, the cooling gas supply unit 40 may supply cooling gas having a constant pressure such that a differential pressure of 0.2 atm or more occurs between the internal pressure and external pressure of the accommodation space S.

Accordingly, the differential pressure between the accommodation space S of the support portion 130 and the outside may be maintained at a certain level, and a flow rate of the cooling gas flowing through the accommodation space S of the support portion 130 may be increased, thereby improving cooling efficiency.

There is no particular limitation on the configuration of the sealing member 140 in the substrate support unit 100 according to an example embodiment of the present inventive concept, and as long as the sealing member 140 is configured to seal a lower portion of the accommodation space S of the support portion 130, the sealing member 140 may be implemented in various forms depending on the specific structure of the substrate support unit 100, and may be generally described as a seal. The sealing member 140 may therefore be formed of an O-ring or other ring-shaped structure in one example, formed of a flexible material such as rubber or a synthetic plastic. In addition, the dispositional structure, dispositional position, and shape of the inlet portion and the outlet portion may be implemented in various ways, which will be described later.

The substrate support unit 100 according to an example embodiment of the present inventive concept may further include a lifting driving member 190 connected to a lower portion of the support portion 130, as shown in FIG. 2, and lifting the chuck 110. The lifting driving member 190, also described as a lifting driver, may be installed in the chamber 10 so as to be disposed below the support portion 130. The lifting driving member 190 may be a linear motor or a cylinder for lifting the support unit 130.

In addition, when treating a substrate in the substrate support unit 100 according to an example embodiment of the present inventive concept, the chuck 110 may be configured to support the substrate in a rotated state. In an example embodiment, the support portion 130 may be connected to the shaft portion 120 to rotate the chuck 110.

The configuration, structure, and disposition of the chamber 10, the substrate support unit 100, and the gas injection unit 20 of the apparatus for treating a substrate 1 shown in FIGS. 1 and 2 are exemplary, and may vary in example embodiments.

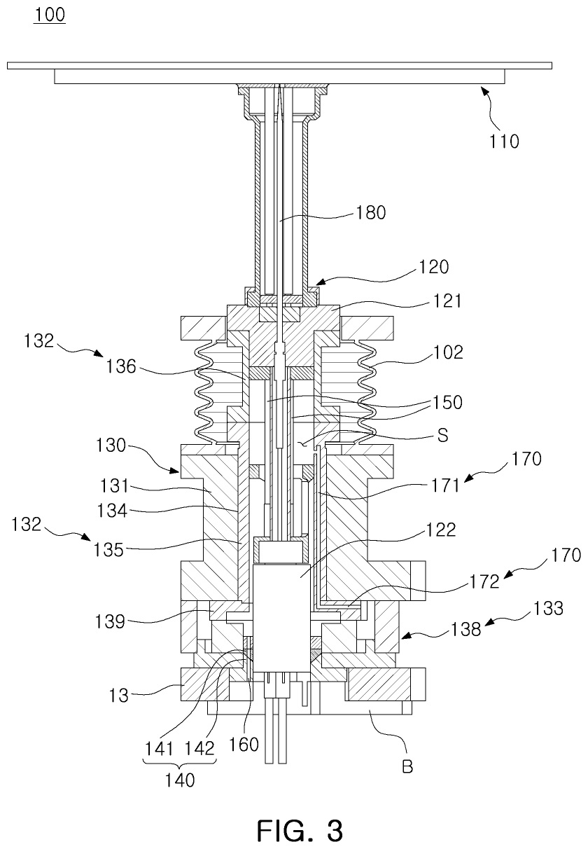

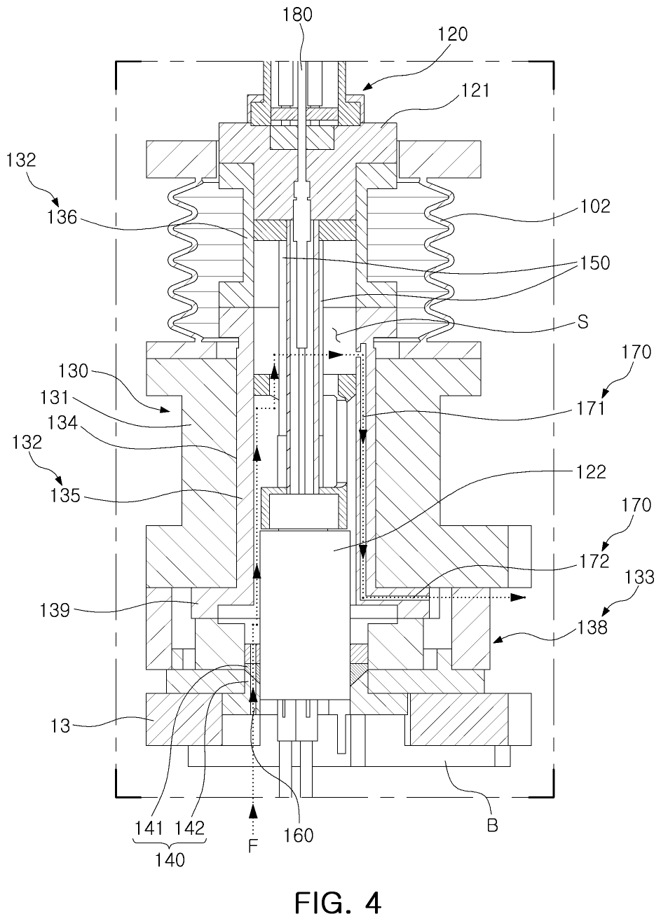

A structure of the substrate support unit 100 including the chuck 110, the shaft portion 120, the support portion 130 connected to the shaft portion 120 to rotate the chuck 110, the sealing member 140, the electric line 150, the inlet portion 160, and the outlet portion will be described in more detail below with reference to FIGS. 3 and 4.

FIG. 3 is a schematic cross-sectional view of a substrate support unit according to an example embodiment, and FIG. 4 is a schematic cross-sectional view illustrating some configurations of a substrate support unit according to an example embodiment.

Referring to FIGS. 3 and 4, a substrate support unit 100 may include a chuck 110, a shaft portion 120, a support portion 130 connected to the shaft portion 120 to rotate the chuck 110, a sealing member 140, an electric line 150, an inlet portion 160, and an outlet portion 170. The substrate support unit 100 may be installed not only in the apparatus for treating a substrate 1 described above with reference to FIGS. 1 and 2, but also in various semiconductor manufacturing apparatuses such as an etching apparatus. In particular, the substrate support unit 100 may be installed in a semiconductor manufacturing apparatus using plasma.

The shaft portion 120 may include a flange 121 disposed on an outer peripheral surface of the shaft portion 120 and coupled to the support portion 130. The flange 121 may pass through a through-hole 14 formed in a cylindrical portion 12 provided at the bottom of the chamber 10. The shaft portion 120 may include a slip ring 122 provided below the shaft portion 120 to supply power to the electric line 150 connected to the heating member 112 of the chuck 110 in a rotated state. The slip ring 122 may connect the electric line 150 to an external power supply source 30. The slip ring 122 may be inserted into the support portion 130, and a space between a lower end of the slip ring 122 and the support portion 130 may be sealed by the sealing member 140.

The support portion 130 may be connected to the shaft portion 120 to rotate the chuck 110, the support portion 130 may include a fixing member 131, a rotation member 132, and a rotation driving member 133.

The fixing member 131 may have a hollow hole 134 (e.g., an internal space) into which the rotation member 132 is inserted and coupled. The fixing member 131 may be a cylindrical block or frame, onto which other components are attached.

The rotation member 132 may be located between a sidewall of the fixing member 131 that forms the internal space 134, and the shaft portion 120, and may be rotatably coupled to the fixing member 131 together with the chuck 110 and the shaft portion 120. The rotation member 132 may have an accommodation space S in which the shaft portion 120 is accommodated.

In an example embodiment, as shown in FIGS. 1 to 3, the rotation member 132, which may be a rotation cylinder or rotation shaft, may include a first rotation member 135 and an adapter 136. The first rotation member 135 may be located between the sidewall of the fixing member 131 that forms the internal space 134, and the shaft portion 120, and may form a portion of the accommodation space S. The first rotation member 135 may be coupled to a lower portion of the adapter 136. Each of the first rotation member 135 and adapter 136 may have a cylindrical shape and may be described individually or collectively as a rotation cylinder, rotation cylinder portion, or rotation shaft. The adapter 136 may be connected between the flange 121 disposed on an outer peripheral surface of the shaft portion 120 and an upper portion of the first rotation member 135, and may form another portion of the accommodation space S. For example, the accommodation space S of the support portion 130 may be formed inside the first rotation member 135 and the adapter 136. In this embodiment, it is illustrated that the rotation member 132 includes an adapter 136 and a first rotation member 135 coupled to the adapter 136, but the present inventive concept is not limited thereto, and the adapter and the first rotation member may be composed of one rotation member integrally formed.

In an example embodiment, the fixing member 131 and the rotation member 132 may form a magnetic fluid seal assembly, and as an example, the fixing member 131 and the first rotation member 135 may form a magnetic fluid seal assembly. For example, the magnetic fluid seal assembly may include a fixing member 131 and may include the first rotation member 135, wherein the fixing member 131 is coupled to an outer peripheral surface of the first rotation member 135. For example, the outer peripheral surface of the first rotation member 135 may face an inner surface, or inner sidewall, of the fixing member 131. The magnetic fluid seal assembly may additionally include a magnetic fluid (not shown) provided between the first rotation member 135 and the fixing member 131, a bearing (not shown), and a magnet (not shown). In this case, the rotation driving member 133 may be disposed below the magnetic fluid seal assembly. The fixing member 131 may include a magnetic fluid sealing a space between the first rotation member 135 and the fixing member 131 by a bearing supporting the first rotation member 135 to rotate freely within the internal space 134 of the fixing member 131 and a magnetic force. In an exemplary embodiment, the magnetic fluid may maintain a liquid state and include a magnetic material. The magnetic fluid may maintain a sealed state even when the first rotation member 135 rotates, thereby preventing foreign substances from entering from the outside.

The rotation driving member 133 may be disposed below the fixing member 131 and the rotation member 132, and may be connected to the rotation member 132 to provide rotational force. The rotation driving member 133 may communicate with the shaft portion 120 to serve to rotate the chuck 110. As an example, the rotation driving member 133, also described as a rotation driver, may include a rotation motor 137 and a power transmission member 138 (also described as a power transmission). The rotation motor 137 may be connected to the shaft portion 120 through the power transmission member 138 and the rotation member 132. The rotation motor 137 may be installed on an installation frame 13 provided on the main body 11 disposed below the chamber 10 by a fixing bracket B.

The slip ring 122 of the shaft portion 120 may protrude into the rotation driving member 133 from the accommodation space S of the support portion 130 and inserted thereinto. The slip ring may have a cylindrical shape, and may be configured to allow the transmission of power and electrical signals to the shaft portion 120. The sealing member 140 may be disposed between a lower end of the slip ring 122 and the rotation driving member 133 to seal a lower portion of the accommodation space S. In an example embodiment, the slip ring 122 of the shaft portion 120 may protrude and be inserted into the power transmission member 138 in the accommodation space S of the support portion 130, and the sealing member 140 may be disposed between the lower end of the slip ring 122 and the power transmission member 138, to seal the lower portion of the accommodation space S of the support portion 130 and block the same from the outside.

In an example embodiment, the sealing member 140 may include a sealing pad 141 and a sealing bracket 142 to which the sealing pad 141 is coupled. The sealing pad 141 may be formed of a plastic material, and in an exemplary embodiment, the sealing pad 141 may be formed of a polytetrafluoroethylene (PTFE) material. The sealing bracket 142 may be formed of the same material as the sealing pad 141, for example, the sealing bracket 142 may be formed of polytetrafluoroethylene material, but the material of the sealing bracket 142 is not limited thereto, and may also be formed of other materials. However, the present inventive concept is not limited to this, and sealing members having various shapes and materials can be used as needed.

The sealing member 140 may be provided with an inlet portion 160, also described as an inlet, an inlet port, or an inlet opening, communicating with the accommodation space S of the support portion 130 and through which cooling gas cooling the electric line 150 flows into the accommodation space S. There is no particular limitation on the shape of the inlet portion 160, and one inlet portion 160 having a slit shape may be disposed in the sealing member 140 to secure a difference between a pressure of the accommodation space S of the support part 130 and an external pressure, but the present inventive concept is not limited thereto, and a plurality of inlet portions 160 may be disposed.

Cooling gas flowing in from the inlet portion 160 of the sealing member 140 may pass through a gap between an inside of the power transmission member 138 (e.g., an inner surface of the power transmission member 138) and the slip ring 122 (e.g., an outer surface of the slip ring 122), and the cooling gas may flow into the accommodation space S of the support portion 130. An outlet portion 170 communicating with the accommodation space S and through which the cooling gas flows out may be disposed in the support portion 130. In an example embodiment, the outlet portion 170, also described as an outlet or outlet opening, may be disposed on the rotation member 132 of the support portion 130, and may be disposed on the first rotation member 135 as shown in FIGS. 1 to 4. There is no particular limitation on the shape of the outlet portion 170, and one outlet portion 170 having a slit shape may be disposed in the first rotation member 135 to secure a difference between a pressure of the accommodation space S and an external pressure, but the present inventive is not limited thereto, and a plurality of outlet portions 170 may be disposed.

As shown in FIGS. 3 and 4, the outlet portion 170 may include a first outlet portion 171, also described as a first outlet segment, disposed on the rotation member 132 and a second outlet portion 172, also described as a second outlet segment disposed in or on a coupling member 139 connecting the rotation driving member 133 and the rotation member 132. As an example, the first outlet portion 171 may extend radially outward from an inner wall surface of the first rotation member 135 and may extend to a lower end surface of the first rotation member 135. The second outlet portion 172 may be connected to the first outlet portion 171 located on the lower end surface of the first rotation member 135 and may be formed by penetrating an outer wall surface of the coupling member 139 (e.g., by penetrating an end surface, such as a surface perpendicular to a direction in which the second outlet portion extends). However, the present inventive concept is not limited to this, and the outlet portion may be implemented in various forms as long as it is disposed on a rotation component communicating with the accommodation space of the support portion and rotating.

In another example embodiment, an outlet portion may not be disposed on the first rotation member 135 but may be disposed in the adapter 136. In another example embodiment, an outlet portion may be disposed in each of the first rotation member and the adapter.

In the apparatus for treating a substrate 1 according to an example embodiment of the present inventive concept, as heat generated by the heating member 112 in the process of heating the substrate by the chuck 110 is transferred to the electric line 150 and the slip ring 122 through the electric line 150, resistance of the slip ring 122 (e.g., electrical resistance) may increase. As the resistance of the slip ring 122 continues to increase due to overheating, defects phenomena such as arcing may occur.

In the apparatus for treating a substrate 1 of the present inventive concept, by disposing the inlet portion 160 introducing cooling gas into the accommodation space S of the support portion 130 sealed by the sealing member 140, which accommodation space S is not rotated, and disposing the outlet portion 170 discharging the cooling gas of the accommodation space S in the rotation member 132 (e.g., with a body of the rotation member 132), which rotates, the cooling gas supplied from the cooling gas supply unit 40 may flow into the accommodation space S of the support portion sealed by the sealing member 140 through the inlet portion 160 and a flow rate thereof may be increased by the rotation of the rotation member, so that the electric line 150 and the slip ring 122 may be efficiently cooled and then the cooling gas may be smoothly discharged externally through the outlet portion 170. Accordingly, by cooling the electric line 150 and the slip ring 122, it is possible to effectively prevent defective phenomena such as arcing on surrounding members of the electric line 150, such as the slip ring 122.

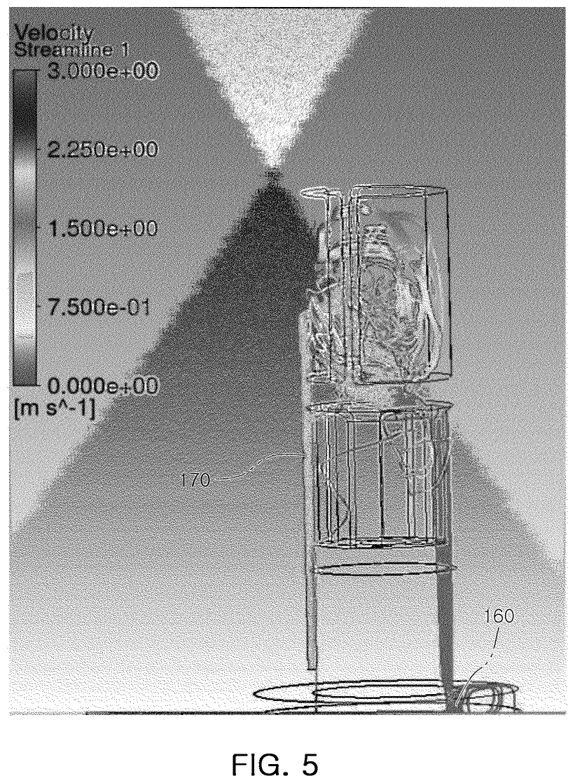

FIG. 5 is a diagram illustrating a flow of cooling gas flowing inside a substrate support unit including a sealing member, an inlet portion disposed in the sealing member, and an outlet portion disposed in the rotation member according to an example embodiment, which is a diagram illustrating that the cooling gas flowing through an empty space inside a substrate support unit. As seen in FIG. 5, through a structure in which the inlet portion 160 is disposed in the sealing member disposed between a lower end of the slip ring and a rotation driving member and the outlet portion 170 is disposed in the first rotation member, the cooling gas flowing out through the outlet portion of the first rotation member while flowing into the accommodation space of the support portion through the inlet portion of the sealing member shows that a flow rate is effectively increased, and it can be confirmed that the cooling efficiency for the electric lines and slip rings has been significantly improved as the cooling gas flows to an upper end region of the accommodation space.

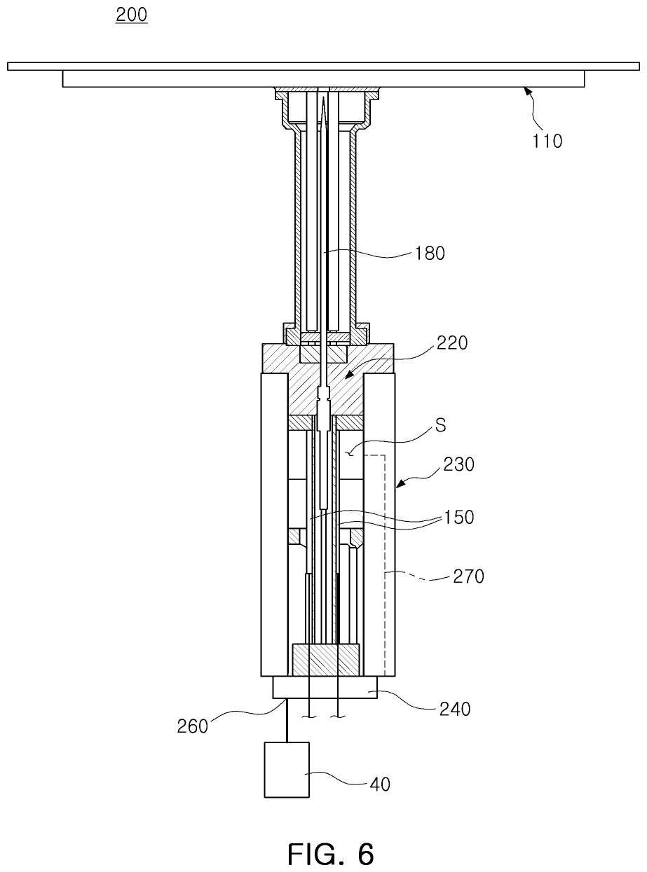

In the above, the apparatus for treating a substrate 1 described with reference to FIGS. 1 to 5 has been described as an example embodiment in which the support portion 130 of the substrate support unit 100 rotates the chuck 110 when treating the substrate, but the present inventive concept is not limited thereto. The support portion may have a structure supporting the chuck in a fixed state without rotating the chuck, which will be described below with reference to FIG. 6.

FIG. 6 is a schematic cross-sectional view of a substrate support unit according to an example embodiment.

Referring to FIG. 6, in the substrate support unit 200 according to an example embodiment, the support portion 230 may be connected to the shaft portion 220 and may have a structure supporting the chuck 110 in a fixed state without rotating the chuck. This will be explained in detail through example embodiments below.

In the apparatus for treating a substrate according to an example embodiment, unlike the embodiment of FIGS. 1 to 4, the support portion 230 may have a structure supporting the chuck 110 in a fixed state without rotating the chuck 110, which may be a structure supporting the shaft portion 220 disposed below the chuck 110.

Referring to FIG. 6, the shaft portion 220 may have an electric line 150 connected to the heating member 112 of the chuck 110 therein and a power supply source (not shown) and a temperature sensor 180 for measuring a temperature of the chuck 110 disposed therein. The shaft portion 220 may be inserted into the accommodation space S of the support portion 230 and may be disposed to extend to a lower portion of the support portion 230.

The sealing member 240 may be disposed below the shaft portion 220 and the support portion 230 to seal a space between a lower end portion of the shaft portion 220 and a lower end portion of the support portion 230. The sealing member 240 may have various structures as long as it seals the space between a lower end portion of the shaft portion 220 and a lower end portion of the support portion 230. For example, the sealing member 240 may have a cylindrical shape with a T-shaped cross section. The sealing member 240 may be formed of a variety of materials, for example, the sealing member 240 may be formed of a plastic material, but the material of the sealing member 240 is not limited thereto, and may also be formed of other materials.

In order to cool the electric line 150 and surrounding members, the substrate support unit 200 according to an example embodiment of the present inventive concept may include an inlet portion 260 through which cooling gas flows into the accommodation space S of the support portion 230 sealed by the sealing member 240 and an outlet portion 270 through which cooling gas flows out from the accommodation space S externally.

The inlet portion 260 may be disposed in the sealing member 240, and the outlet portion 270 may be disposed on a side wall of the support portion 230. A cooling gas supply unit 40 to which cooling gas is supplied may be connected to the inlet portion 260. The cooling gas supply unit 40, which may be a cooling gas supply source such as a vessel filled with cooling gas and a valve for controlling output of the cooling gas, may be connected to the inlet portion 260 and may supply cooling gas having an internal pressure of the accommodation space S of the support portion 230, higher than an external pressure. Accordingly, cooling efficiency may be improved by increasing a flow rate of the cooling gas flowing through the accommodation space S of the support portion 230. In addition, in an example embodiment, the outlet portion 270 may be located higher than the inlet portion 260 in a height direction of the support portion 230. Here, the dispositional position and shape of the inlet portion 260 and the outlet portion 270 are not particularly limited, and may be implemented in various forms. In another example embodiment, both the inlet portion and the outlet portion may be disposed on the support portion 230. For example, the inlet portion may be disposed on a lower end surface of the support portion and the outlet portion may be disposed on the side wall of the support portion. As cooling gas supplied from the cooling gas supply unit 40 may flow into the accommodation space S of the support portion 230 sealed by the sealing member 240 through the inlet portion 260, the electric line 150 of the shaft portion 220 and surrounding members may be cooled and then be discharged externally through the outlet portion 270, so that occurrence of defect phenomena such as arching on the surrounding members of the electric line 150 may be effectively prevented.

According to the substrate support unit and the apparatus for treating a substrate according to an example embodiment of the present inventive concept, by flowing the cooling gas into the internal space in which the electric line of the substrate support unit is disposed, the cooling efficiency of the internal electric line connected to the chuck and the surrounding members of the electric line may be improved.

As set forth above, according to the present inventive concept, a substrate support unit and an apparatus for treating a substrate that can improve cooling efficiency for an internal electric line connected to a chuck and surrounding members of the electric line by flowing cooling gas into an internal space of the substrate support unit on which the electric line is disposed may be provided.

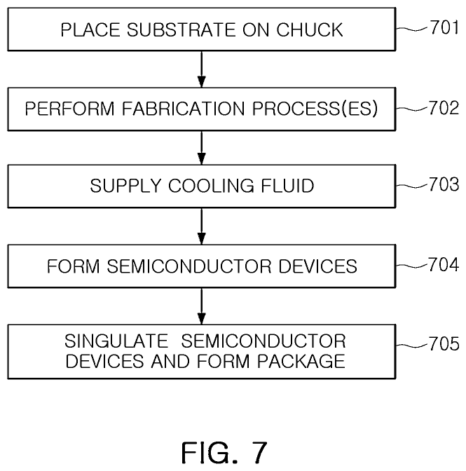

FIG. 7 depicts a method of manufacturing a semiconductor device using an apparatus such as described in FIGS. 1-6, according to one embodiment.

In step 701, a substrate is placed on a chuck in a chamber, such as chuck 110 and chamber 10 of the various embodiments. The substrate may be, for example, a semiconductor substrate on which patterns are already formed and/or are to be formed. However, the invention is not limited thereto, and the substrate may be an insulative substrate or other type of substrate.

In step 702, one or more fabrication processes, such as a deposition process, a lithography process, an etching process, a cleaning process, and the like are performed. For example, representative methods for forming a thin film on a substrate in a deposition process include chemical vapor deposition (CVD) and atomic layer deposition (ALD). In such a deposition process, various reactants may be used to form a thin film on a surface of the substrate heated to a process temperature. As part of step 702, in order to heat the substrate during the deposition process, a substrate support apparatus such as support unit 130 as well as chuck 110 is heated, for example, by receiving power through electric line 150 connected to a power supply source 30.

In step 703, which may occur at the same time as step 702, a cooling fluid (e.g., cooling gas) is supplied to the apparatus, for example, through an inlet portion 160 of the various embodiments, passes through the apparatus to cool the support unit 130 and other components, and then exits the apparatus through an outlet portion 170. The inlet portion 160 and outlet portion 170 may be arranged according to one of the various embodiments.

In step 704, additional processes are performed on the substrate to result in a wafer that includes a plurality of semiconductor devices such as semiconductor memory chips, or semiconductor logic chips. These additional processes may be performed in the same chamber on the same chuck 110, or may be performed elsewhere.

In step 705, the semiconductor devices formed during steps 701-704 may be singulated and may be placed on a package substrate and encapsulated to form a semiconductor device such as a semiconductor package.

While example embodiments have been shown and described above, it will be apparent to those skilled in the art that modifications and variations could be made without departing from the scope of the present inventive concept as defined by the appended claims.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

What is claimed is:

1. A substrate support unit, comprising:
a chuck having an upper surface on which to mount a substrate, and including a heater for heating the substrate;
a shaft assembly supporting a lower portion of the chuck, and including an electric line connected to the heater;
a support assembly having an accommodation space surrounding and accommodating a portion of the shaft assembly, and supporting the shaft assembly;
a seal sealing a lower portion of the accommodation space;
an inlet communicating with the accommodation space and configured to transfer cooling gas for cooling the electric line into the accommodation space, the inlet being disposed in one of the support assembly and the seal; and
an outlet disposed in the support assembly, communicating with the accommodation space, and configured to transfer the cooling gas out of the support assembly.

2. The substrate support unit of claim 1, wherein the support assembly comprises:
a fixing member having an internal space formed therein;
a rotation cylinder located between a sidewall of the fixing member that forms the internal space, and the shaft assembly, rotatably coupled to the fixing member together with the chuck and the shaft assembly, and having the accommodation space; and
a rotation driver disposed below the fixing member and the rotation cylinder, and connected to the rotation cylinder to provide rotational force.

3. The substrate support unit of claim 2, wherein:
the shaft assembly comprises a slip ring protruding into the rotation driver from the accommodation space and inserted into the accommodation space, and connecting the electric line to a power supply source, and
the seal is disposed between a lower end of the slip ring and the rotation driver.

4. The substrate support unit of claim 3, wherein:
the inlet is disposed in the seal to pass through the seal, and
the outlet is disposed in the rotation cylinder.

5. The substrate support unit of claim 4, wherein the outlet is connected to a first opening disposed in the rotation cylinder and a second opening disposed in a coupling member connecting the rotation driver and the rotation cylinder.

6. The substrate support unit of claim 2, wherein the rotation cylinder comprises:
a first rotation cylinder portion located between the shaft assembly and the sidewall of the fixing member that forms the internal space, and defining a portion of the accommodation space; and
an adapter connected between an upper portion of the first rotation cylinder portion, and a flange disposed on an outer peripheral surface of the shaft assembly and, and defining another portion of the accommodation space,
wherein the outlet is disposed in the rotation cylinder.

7. The substrate support unit of claim 6, wherein the fixing member and the first rotation cylinder portion form a magnetic fluid seal assembly.

8. The substrate support unit of claim 2, wherein the rotation cylinder comprises:
a first rotation cylinder portion located between shaft assembly and sidewall of the fixing member that forms the internal space, and defining a portion of the accommodation space; and
an adapter connected between an upper portion of the first rotation cylinder portion and a flange disposed on an outer peripheral surface of the shaft assembly, and defining another portion of the accommodation space,
wherein the outlet is disposed in the adapter.

9. The substrate support unit of claim 1, wherein the inlet is disposed on a lower end surface of the support assembly or in the seal, and the outlet is disposed on a sidewall of the support assembly and is located higher than the inlet in a height direction of the support assembly.

10. The substrate support unit of claim 1, further comprising:
a lifting driving member connected to a lower portion of the support assembly and configured to lift the chuck.

11. An apparatus for treating a substrate, comprising:
a chamber;
a substrate support unit disposed in the chamber and configured to support a substrate; and
a gas injection unit disposed above the substrate support unit, and configured to inject process gas onto the substrate,
wherein the substrate support unit includes:
a chuck having an upper surface on which to mount a substrate, and including a heater for heating the substrate;
a shaft supporting a lower portion of the chuck, and including an electric line connected to the heater;
a support having an accommodation space surrounding and accommodating a portion of the shaft, and supporting the shaft;
a seal sealing a lower portion of the accommodation space;
an inlet communicating with the accommodation space and configured to transfer cooling gas for cooling the electric line into the accommodation space, the inlet being disposed in one of the support and the seal; and
an outlet disposed in the support, communicating with the accommodation space, and configured to transfer the cooling gas out of the support.

12. The apparatus for treating a substrate of claim 11, wherein the support comprises:
a fixing block having an internal space formed therein;
a rotation cylinder located between the shaft and a sidewall of the fixing block that forms the internal space, rotatably coupled to the fixing block together with the chuck and the shaft, and having the accommodation space; and
a rotation driver disposed below the fixing block and the rotation cylinder, and connected to the rotation cylinder to provide rotational force.

13. The apparatus for treating a substrate of claim 12, wherein:
the shaft comprises a slip ring protruding into the rotation driver from the accommodation space and inserted into the accommodation space, and connecting the electric line to a power supply source,
the seal is disposed between a lower end of the slip ring and the rotation driver, and
the inlet is disposed in the seal, and the outlet is disposed in the rotation cylinder,

14. The apparatus for treating a substrate of claim 12, wherein the rotation cylinder comprises:
a first rotation cylinder located between the internal space and the shaft, and defining a first portion of the accommodation space; and
an adapter connected between an upper portion of the first rotation cylinder and a flange disposed on an outer peripheral surface of the shaft, and defining a second portion of the accommodation space,
wherein the outlet is disposed in the first rotation cylinder.

15. The apparatus for treating a substrate of claim 11, further comprising:
a cooling gas supply source connected to the inlet, and connected to supply cooling gas having an internal pressure within the accommodation space higher than an external pressure.

16. The apparatus for treating a substrate of claim 11, further comprising:
a lifting driver connected to a lower portion of the support and configured to lift the chuck.

17. An apparatus for treating a substrate, comprising:
a chamber;
a substrate support unit disposed in the chamber and configured to support a substrate; and
a gas injection unit disposed above the substrate support unit and configured to inject process gas onto the substrate,
wherein the substrate support unit includes:
a chuck having an upper surface on which to mount a substrate, and including a heating member for heating the substrate;
a shaft portion supporting a lower portion of the chuck, having an electric line connected to the heating member disposed thereon, and including a slip ring connecting the electric line to a power supply source;
a support portion having an accommodation space surrounding and accommodating a portion of the shaft portion, and connected to the shaft portion to rotate the chuck;
a seal sealing a lower portion of the accommodation space;
an inlet communicating with the accommodation space and located to transfer cooling gas for cooling the electric line into the accommodation space, the inlet disposed in the seal; and
an outlet communicating with the accommodation space and located to transfer the cooling gas from the accommodation space to an outside of the substrate support unit, the outlet connected to an opening in a rotation cylinder of the substrate support unit.

18. The apparatus for treating a substrate of claim 17, wherein the shaft portion comprises a flange accommodated in a cylindrical portion provided at the bottom of the chamber and disposed on an outer peripheral surface of the shaft portion,
wherein the support portion comprises:
an adapter coupled to the flange;
a magnetic fluid seal assembly including a rotation member coupled to a lower portion of the adapter and a fixing member coupled to an outer peripheral surface of the rotation member; and
a rotation driving member disposed below the magnetic fluid seal assembly and connected to the rotation member to provide rotational force,
wherein the accommodation space is formed inside the adapter and the rotation member, and
wherein the seal is disposed between a lower end of the slip ring and the rotation driving member.

19. The apparatus for treating a substrate of claim 17, further comprising:
a cooling gas supply unit connected to the inlet, and configured to supply cooling gas having an internal pressure in the accommodation space higher than an external pressure.

20. The apparatus for treating a substrate of claim 17, wherein a cylindrical portion is provided at the bottom of the chamber which is disposed so that the shaft portion penetrates the cylindrical portion, and
a bellows pipe disposed to surround the support portion is installed inside the cylindrical portion.
